(19) United States
(12) Patent Application Publication
(10) Pub. No.: US 2019/0081166 A1
(43) Pub. Date: Mar. 14, 2019

(54) GATE-ALL-AROUND DEVICE AND METHOD FOR FABRICATING THE SAME

(71) Applicant: ELECTRONICS AND TELECOMMUNICATIONS RESEARCH INSTITUTE, Daejeon (KR)

(72) Inventors: Jae Won DO, Daejeon (KR); Dong Min KANG, Daejeon (KR); Dong-Young KIM, Daejeon (KR); SEONG-IL KIM, Daejeon (KR); Hae Cheon KIM, Daejeon (KR); Byoung-Gue MIN, Sejong-si (KR); Min Jeong SHIN, Daejeon (KR); Hokyun AHN, Daejeon (KR); Hyung Sup YOON, Daejeon (KR); Sang-Heung LEE, Daejeon (KR); Jongmin LEE, Daejeon (KR); Jong-Won LIM, Daejeon (KR); Sungjae CHANG, Daejeon (KR); Yoo Jin JANG, Daejeon (KR); Hyunwook JUNG, Daejeon (KR); Kyu Jun CHO, Daejeon (KR); Hong Gu JI, Daejeon (KR)

(73) Assignee: ELECTRONICS AND TELECOMMUNICATIONS RESEARCH INSTITUTE, Daejeon (KR)

(21) Appl. No.: 16/028,612

(22) Filed: Jul. 6, 2018

(30) Foreign Application Priority Data
Sep. 8, 2017 (KR) 10-2017-0115461
Jan. 16, 2018 (KR) 10-2018-0005714

(51) Int. Cl. H01L 29/778; H01L 29/423; H01L 29/66; H01L 29/06; H01L 29/10; H01L 29/205

(52) U.S. Cl. CPC H01L 29/7783; H01L 29/42316; H01L 29/66462; H01L 29/2003; H01L 29/1029; H01L 29/205; H01L 29/0653

(57) ABSTRACT

Provided is a gate-all-around device. The gate-all-around device includes a substrate, a pair of heterojunction source/drain regions provided on the substrate, a heterojunction channel region provided between the pair of heterojunction source/drain regions, and a pair of ohmic electrodes provided on the pair of heterojunction source/drain regions, respectively. Each of the pair of heterojunction source/drain regions includes a pair of two-dimensional electron gas layers. The pair of ohmic electrodes extends toward an upper surface of the substrate and pass through the pair of heterojunction source/drain regions, respectively.

### CROSS-REFERENCE TO RELATED APPLICATIONS

This U.S. non-provisional patent application claims priority under 35 U.S.C. § 119 of Korean Patent Application Nos. 10-2017-0115461, filed on Sep. 8, 2017, and 10-2018-0005714, filed on Jan. 16, 2018, the entire contents of which are hereby incorporated by reference herein.

### BACKGROUND

The present inventive concepts relates to a gate-all-around device and a method of fabricating the same.

Gallium nitride (GaN), which is a nitride semiconductor, is a direct transition semiconductor, and has a high field electron transfer rate (e.g., 2×10⁷ cm/s) and a high heat transfer breakdown field (e.g., 3×10⁶ V/cm) and a high band gap (e.g., 3.4 eV), and forms a heterojunction structure with aluminum gallium nitride (AlGaN) to provide a high electron density on a two-dimensional scale, so that high electron mobility transistor (HEMT) may be formed, which is widely used in applications requiring high temperature and high frequency and high output.

### SUMMARY

Some embodiments of the present inventive concepts provide a gate-all-around device with improved electrical characteristics and reliability.

Some embodiments of the present inventive concepts provide a method of fabricating a gate-all-around device having improved process difficulty and reliability.

According to example embodiments of the present inventive concepts, a gate-all-around device including: a substrate; a pair of heterojunction source/drain regions provided on the substrate; a heterojunction channel region provided between the pair of heterojunction source/drain regions; and a pair of ohmic electrodes provided on the pair of heterojunction source/drain regions, respectively, wherein each of the pair of heterojunction source/drain regions includes a pair of two-dimensional electron gas layers, and the pair of ohmic electrodes may extend toward an upper surface of the substrate and pass through the pair of heterojunction source/drain regions, respectively.

In some exemplary embodiments, each of the pair of ohmic electrodes may be electrically connected to the pair of two-dimensional electron gas layers.

In some exemplary embodiments, each of the pair of heterojunction source/drain regions may include: a pair of first nitride semiconductor films spaced apart from each other along a direction perpendicular to the upper surface of the substrate; and a second nitride semiconductor film interposed between the pair of first nitride semiconductor films.

In some exemplary embodiments, the gate-all-around device may further include: an insulating layer interposed between each of the pair of heterojunction source/drain regions and the substrate; and an air gap provided between the heterojunction channel region and the substrate.

In some exemplary embodiments, the heterojunction channel region may include: a second nitride semiconductor film extending in the first direction; and a first nitride semiconductor film surrounding the second nitride semiconductor film.

In some exemplary embodiments, the gate-all-around device may further include a gate electrode surrounding the heterojunction channel region, wherein the first nitride semiconductor film may be interposed between the second nitride semiconductor film and the gate electrode.

In some exemplary embodiments, each of the gate electrode and the heterojunction channel region may be provided in plural, and the plurality of gate electrodes may surround the plurality of heterojunction channel regions.

According to example embodiments of the present inventive concepts, a method of fabricating a gate-all-around device includes: forming a first nitride semiconductor film and a second nitride semiconductor film sequentially stacked on a substrate; sequentially patterning the second nitride semiconductor film and the first nitride semiconductor film to form a first recess region and a second recess region; forming a third nitride semiconductor film on an upper surface of the second nitride semiconductor film and side surfaces of the first and second nitride semiconductor films exposed by each of the first and second recess regions; forming a gate electrode on the first and third nitride semiconductor films disposed between the first and second recess regions; and forming first and second ohmic electrodes on the third nitride semiconductor film, the first and second ohmic electrodes being spaced apart from each other in a first direction parallel to an upper surface of the substrate with the gate electrode therebetween.

In some exemplary embodiment, the method may further include: forming an insulating layer interposed between the first nitride semiconductor film and the substrate; and providing an etchant into the first and second recess regions to remove the insulating layer disposed between the first and second recess regions, wherein the insulating layer may be removed to form an air gap between the first nitride semiconductor film and the substrate.

In some exemplary embodiment, the gate electrode may cover an upper surface of the third nitride semiconductor film and extend along surfaces of the third nitride semiconductor film exposed by the first recess region, the air gap, and the second recess region.

In some exemplary embodiment, the forming of the first and second ohmic electrodes may include: forming third recessed regions penetrating the first to third nitride semiconductor films on both sides of the gate electrode; and depositing metals on the third nitride semiconductor film to fill the third recess regions.

### BRIEF DESCRIPTION OF THE FIGURES

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIGS. 1, 2, 3, 4A, 5A, 6A, 7A, 8A, and 9A are perspective views illustrating a method of fabricating a gate-all-around device according to exemplary embodiments of the present inventive concepts.

FIGS. 4B, 5B, 6B, 7B, 8B, and 9B are cross-sectional views respectively taken along lines I-I′ of FIGS. 4A, 5A, 6A, 7A, 8A, and 9A.

FIGS. 4C, 5C, 6C, 7C, 8C, and 9C are cross-sectional views respectively taken along lines II-II′ of FIGS. 4A, 5A, 6A, 7A, 8A, and 9A.

FIGS. 7D, 8D, and 9D are cross-sectional views along lines of FIGS. 7A, 8A, and 9A, respectively.

### DETAILED DESCRIPTION

In order to fully understand the configuration and effects of the technical spirit of the inventive concept, preferred embodiments of the technical spirit of the inventive concept will be described with reference to the accompanying drawings. However, the technical spirit of the inventive concept is not limited to the embodiments set forth herein and may be implemented in various forms and various modifications may be applied thereto. Only, the technical spirit of the inventive concept is disclosed to the full through the description of the embodiments, and it is provided to those skilled in the art that the inventive concept belongs to inform the scope of the inventive concept completely.

Like reference numerals refer to like elements throughout the specification. Embodiments described herein will be described with reference to a perspective view, a front view, a sectional view, and/or a conceptual view, which are ideal examples of the technical idea of the inventive concept. In the drawings, the thicknesses of areas are exaggerated for effective description. Areas exemplified in the drawings have general properties, and are used to illustrate a specific shape of a semiconductor package region. Thus, this should not be construed as limited to the scope of the inventive concept. It will be understood that various terms are used herein to describe various components but these components should not be limited by these terms. These terms are just used to distinguish a component from another component. Embodiments described herein include complementary embodiments thereof.

The terms used in this specification are used only for explaining specific embodiments while not limiting the inventive concept. The terms of a singular form may include plural forms unless referred to the contrary. The meaning of “comprises,” and/or “comprising” in this specification specifies the mentioned component but does not exclude at least one another component.

Hereinafter, preferred embodiments of the technical spirit of the inventive concept are described with reference to the accompanying drawings so that the inventive concept is described in more detail.

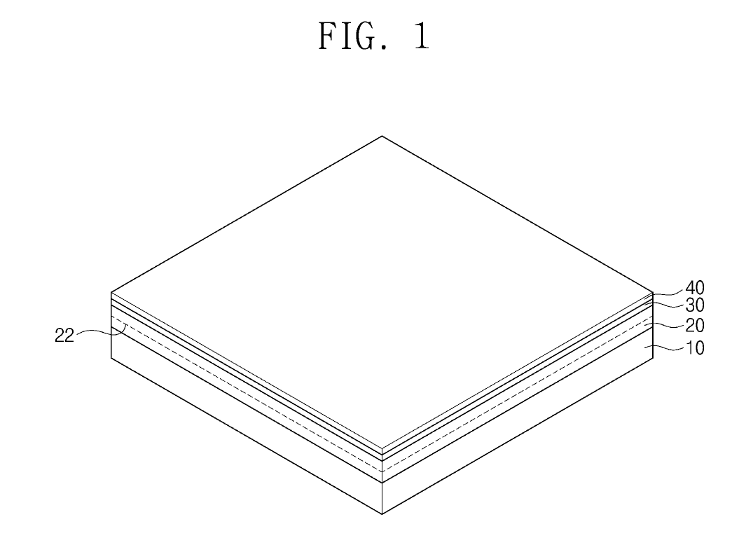

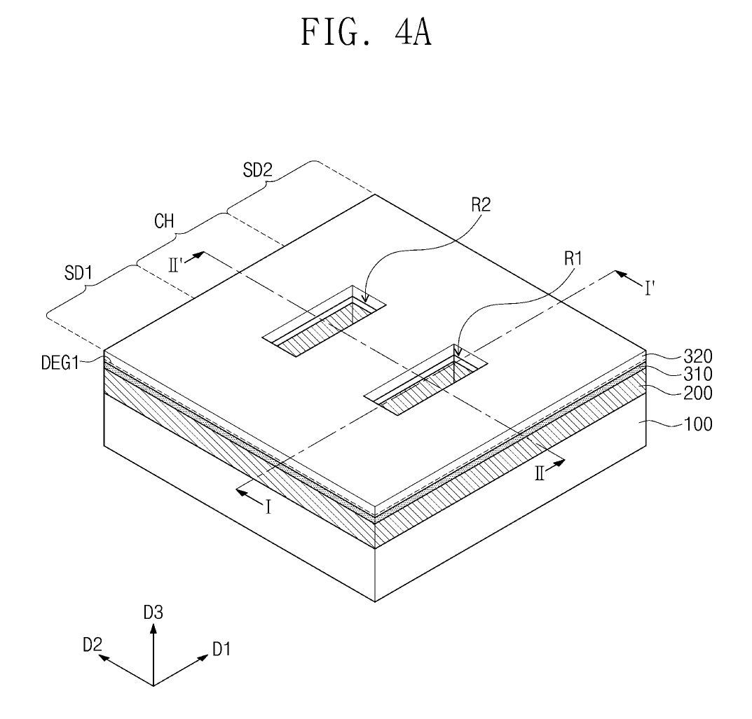

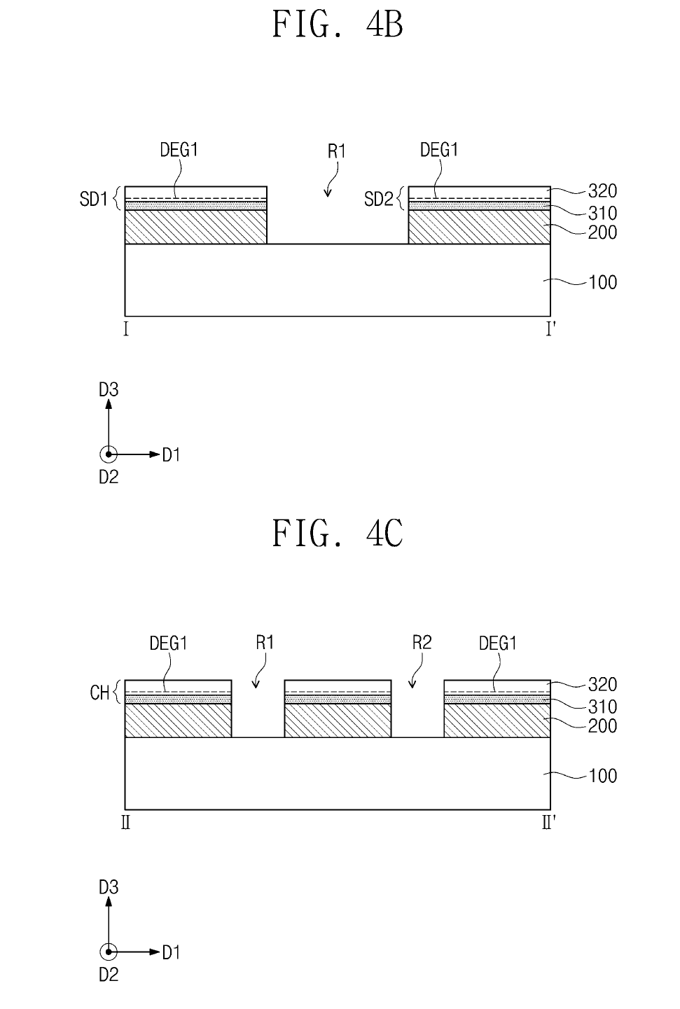

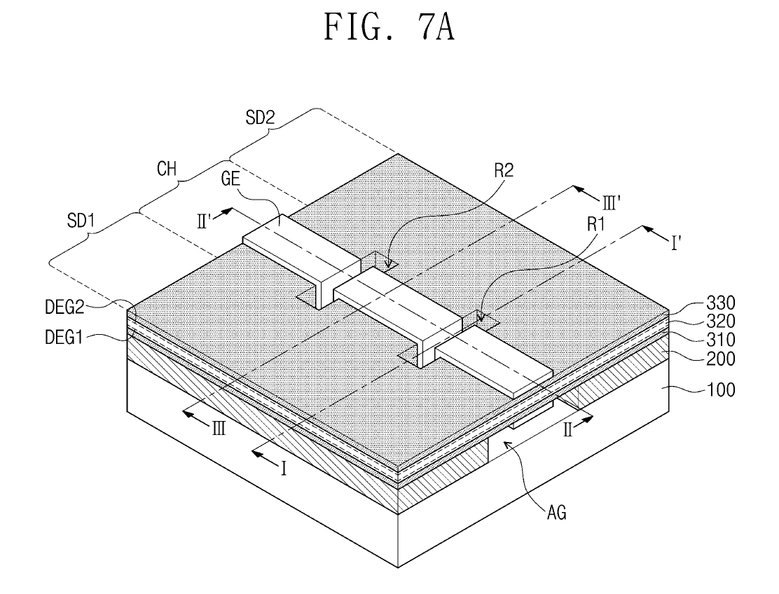

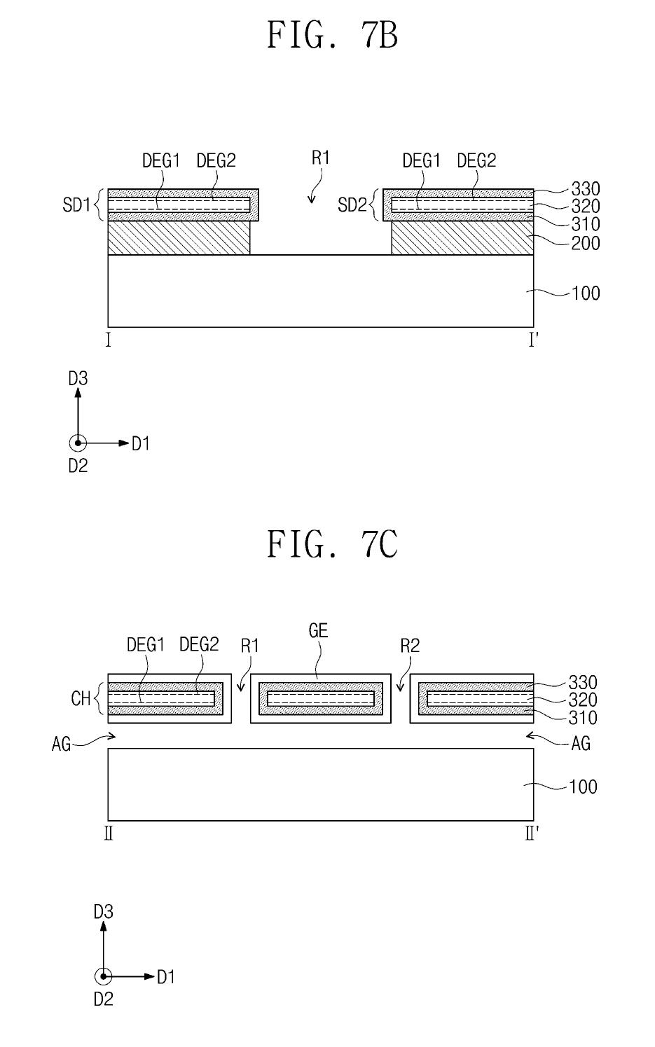

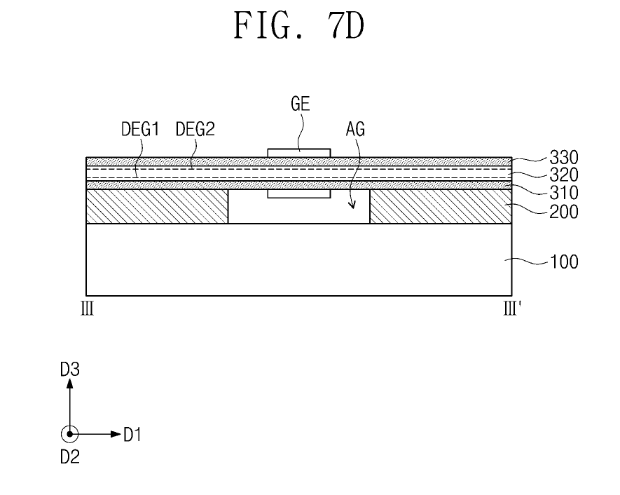

FIGS. 1, 2, 3, 4A, 5A, 6A, 7A, 8A, and 9A are perspective views illustrating a method of fabricating a gate-all-around device according to exemplary embodiments of the present inventive concepts. FIGS. 4B, 5B, 6B, 7B, 8B, and 9B are cross-sectional views respectively taken along lines I-I′ of FIGS. 4A, 5A, 6A, 7A, 8A, and 9A. FIGS. 4C, 5C, 6C, 7C, 8C, and 9C are cross-sectional views respectively taken along lines II-II′ of FIGS. 4A, 5A, 6A, 7A, 8A, and 9A. FIGS. 7D, 8D, and 9D are cross-sectional views along lines of FIGS. 7A, 8A, and 9A, respectively.

Referring to FIG. 1, an auxiliary buffer layer 20 may be formed on an auxiliary substrate 10. In the exemplary embodiments, the auxiliary substrate 10 may be a silicon (Si) substrate, a silicon carbide (SiC) substrate, or a sapphire substrate.

The auxiliary buffer layer 20 may be formed by a chemical vapor deposition (CVD) process (for example, a plasma enhanced chemical vapor deposition (PECVD) process), a physical vapor deposition (PVD) process (e.g., a sputtering process), or an atomic layer deposition (ALD) process. The auxiliary buffer layer 20 may include a nitride semiconductor material. For example, the auxiliary buffer layer 20 may include GaN.

An auxiliary barrier layer 30 may be formed on the auxiliary buffer layer 20. The auxiliary barrier layer 30 may be formed by a chemical vapor deposition (CVD) process (for example, a plasma enhanced chemical vapor deposition (PECVD) process), a physical vapor deposition (PVD) process (e.g., a sputtering process), or an atomic layer deposition (ALD) process. The auxiliary barrier layer 30 may include a semiconductor material that contacts the auxiliary buffer layer 20 to form a two-dimensional electron gas layer (not shown). For example, the auxiliary barrier layer 30 may include AlGaN.

An auxiliary insulating layer 40 may be formed on the auxiliary barrier layer 30. The auxiliary insulating layer 40 may be formed by a chemical vapor deposition (CVD) process (for example, a plasma enhanced chemical vapor deposition (PECVD) process), a physical vapor deposition (PVD) process (e.g., a sputtering process), or an atomic layer deposition (ALD) process. The auxiliary insulating layer 40 may include an insulating material. For example, the auxiliary insulating layer 40 may include silicon oxide (e.g., SiO₂).

A micro-cavity layer 22 may be formed in the auxiliary buffer layer 20. The micro-cavity layer 22 may be a part which is separated in the transfer process described below. The micro-cavity layer 22 may be a part which is separated in the transfer process described below. For example, hydrogen ions may be implanted into the auxiliary buffer layer 20 through the auxiliary insulating layer 40 and the auxiliary barrier layer 30 by an ion implantation process.

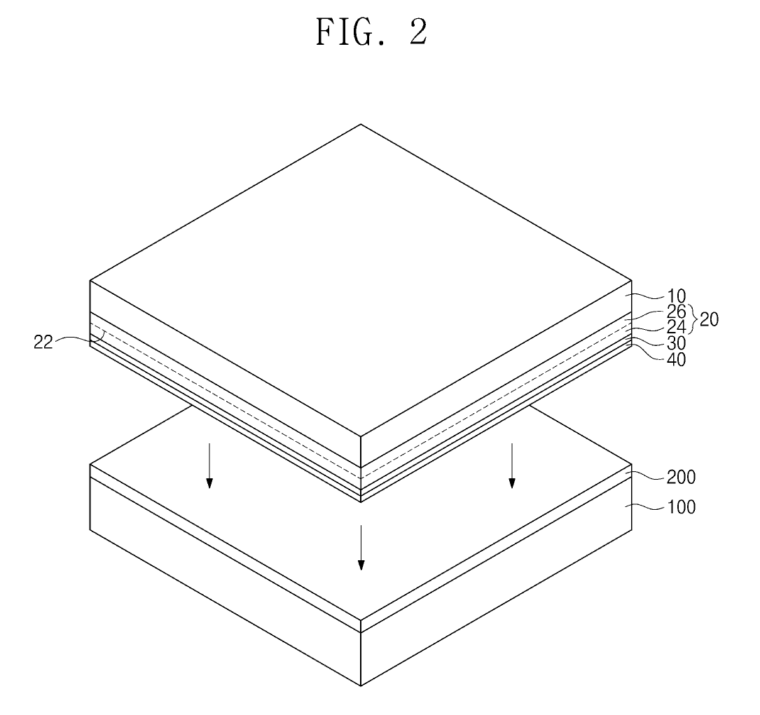

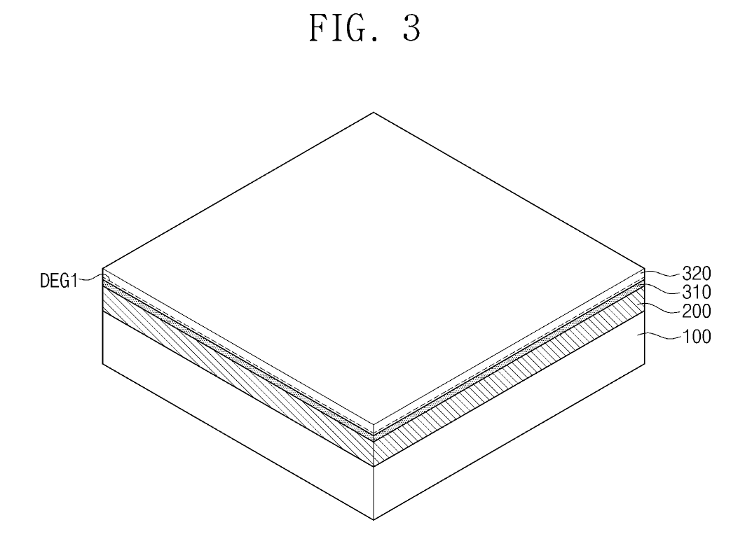

Referring to FIGS. 2 and 3, an insulating layer 200 may be provided on the substrate 100. In the exemplary embodiments, the substrate 100 may be a silicon (Si) substrate, a silicon carbide (SiC) substrate, or a sapphire substrate.

The insulating layer 200 may be formed by a chemical vapor deposition (CVD) process (for example, a plasma enhanced chemical vapor deposition (PECVD) process), a physical vapor deposition (PVD) process (e.g., a sputtering process), or an atomic layer deposition (ALD) process. The insulating layer 200 may include an insulating material. For example, the insulating layer 200 may include silicon oxide (e.g., SiO₂).

The auxiliary buffer layer 20 disposed on the micro-cavity layer 22, the auxiliary barrier layer 30, and the auxiliary insulating layer 40 may be transferred onto the insulating layer 200 on the substrate 100. The transferring process may include separating the upper auxiliary buffer layer 24 and the lower auxiliary buffer layer 26 through a first heat treatment on the auxiliary buffer layer 20, contacting the auxiliary insulating layer 40 to the insulating layer 200, and bonding the insulating layer 200 and the auxiliary insulating layer 40 through a second heat treatment thereon. The boundary between the upper and lower auxiliary buffer layers 24 and 26 may be a micro-cavity layer 22. For example, the first heat treatment process may include heating the auxiliary buffer layer 20 to about 400° C. to about 600° C. For example, the second heat treatment process may include heating the auxiliary insulating layer 40 and the insulating layer 200 to about 1100° C.

The insulating layer 200 and the auxiliary insulating layer 40 may include substantially the same material. Accordingly, the insulating layer 200 and the auxiliary insulating layer 40 may be a single structure having no boundary. Hereinafter, the structure in which the insulating layer 200 and the auxiliary insulating layer 40 are combined is referred to as an insulating layer 200, the auxiliary barrier layer 30 is referred to as a first nitride semiconductor film 310, and the upper auxiliary buffer layer 24 is referred to as a second nitride semiconductor film 320.

Due to the difference in lattice constant between the first nitride semiconductor film 310 and the second nitride semiconductor film 320, the first two-dimensional electron gas layer DEG1 may be formed in the second nitride semiconductor film 320. The first two-dimensional electron gas layer DEG1 may be provided under the second nitride semiconductor film 320 adjacent to the first nitride semiconductor film 310.

Referring to FIGS. 4A, 4B, and 4C, the second nitride semiconductor film 320, the first nitride semiconductor film 310, and the insulating layer 200 may be patterned. The patterning process may include forming a photoresist pattern (not shown) on the second nitride semiconductor film 320 and sequentially etching the second nitride semiconductor film 320, the first nitride semiconductor film 310, and the insulating layer 200 by performing an etching process using the photoresist pattern as an etching mask. The etch process may include a wet etch process, a dry etch process, or a combination of a wet etch process and a dry etch process. For example, the etching process may include performing an electron cyclotron resonance (ECR) plasma etching process or an inductively coupled plasma (ICP) etching process using CF₄ gas, BCl₃ gas, Cl₂ gas, or SF₆ gas. In the etching process, the insulating layer 200 may function as an etch stop layer.

The first heterojunction source/drain region SD1, the heterojunction channel regions CH, and the second heterojunction source/drain region SD2, which are arranged in a first direction parallel to the upper surface of the substrate 100, may be formed by the patterning process. The first and second heterojunction source/drain regions SD1 and SD2 may include a first nitride semiconductor film 310 and a second nitride semiconductor film 320. Each of the first and second heterojunction source/drain regions SD1 and SD2 may extend in a second direction D2 that is parallel to the upper surface of the substrate 100 but intersects the first direction D1. Each of the heterojunction channel regions CH extends along the first direction D1 between the first and second heterojunction source/drain regions SD1 and SD2 to directly contact the first and second heterojunction source/drain regions SD1 and SD2. The heterojunction channel regions CH may be arranged along the second direction D2.

The first recess region R1 and the second recess region R2 may be formed by the patterning process. The first and second recess regions R1 and R2 may be arranged in the second direction D2. Each of the first and second recess regions R1 and R2 may be disposed between a pair of adjacent heterojunction channel regions CH. Each of the first and second recess regions R1 and R2 extends through the second nitride semiconductor film 320, the first nitride semiconductor film 310, and the insulating layer 200, thereby exposing the upper surface of the substrate 100. However, this is an exemplary one. In other exemplary embodiments, the patterning process is performed until the insulating layer 200 is penetrated so that the upper surface of the insulating layer 200 may exposed by the first and second recess regions R1 and R2.

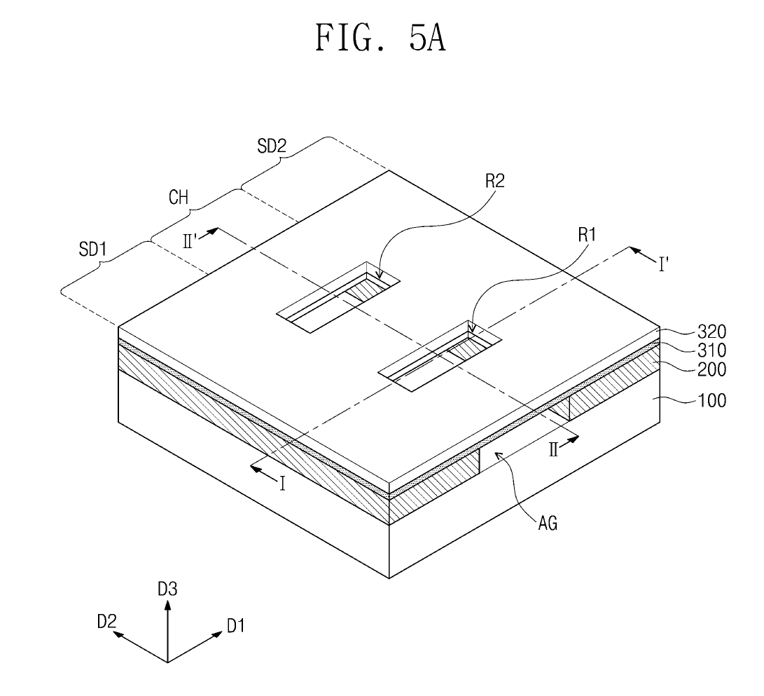

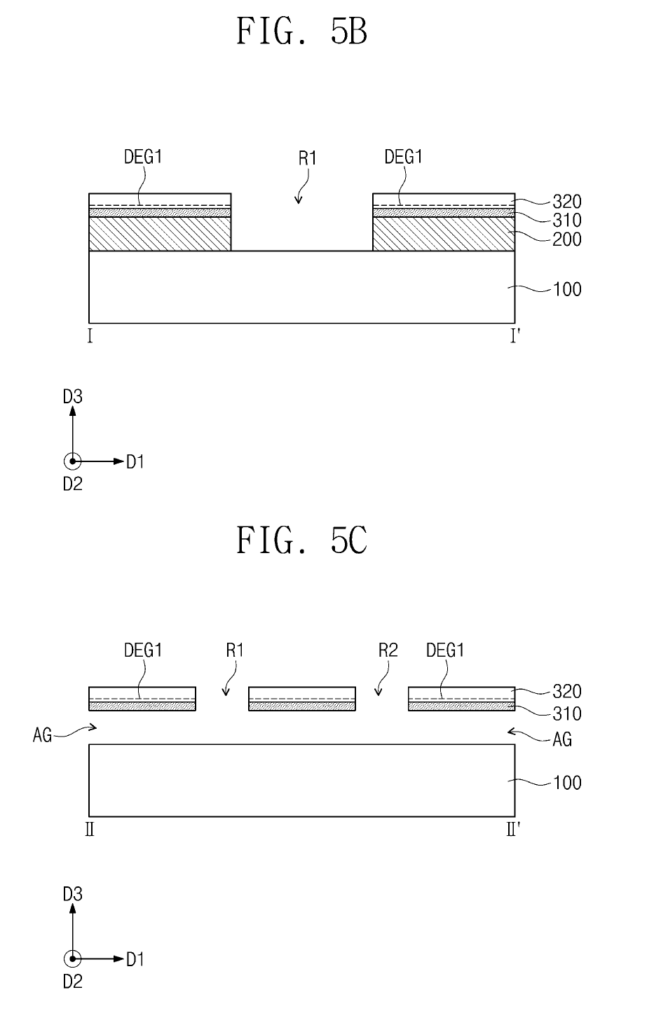

Referring to FIGS. 5A, 5B, and 5C, the insulating layer 200 interposed between the heterojunction channel regions CH and the substrate 100 may be removed. In the exemplary embodiments, removing the insulating layer 200 may include performing a wet etch process that provides an etchant to the insulating layer 200 through the first and second recess regions R1 and R2. For example, the etchant may include a fluorochemical material.

By the wet etching process, air gaps AG may be provided between the heterojunction channel regions CH and the substrate 100. The air gaps AG may expose the upper surface of the substrate 100 and the bottom surface of the first nitride semiconductor film 310. The air gaps AG may be connected to the first and second recess regions R1 and R2.

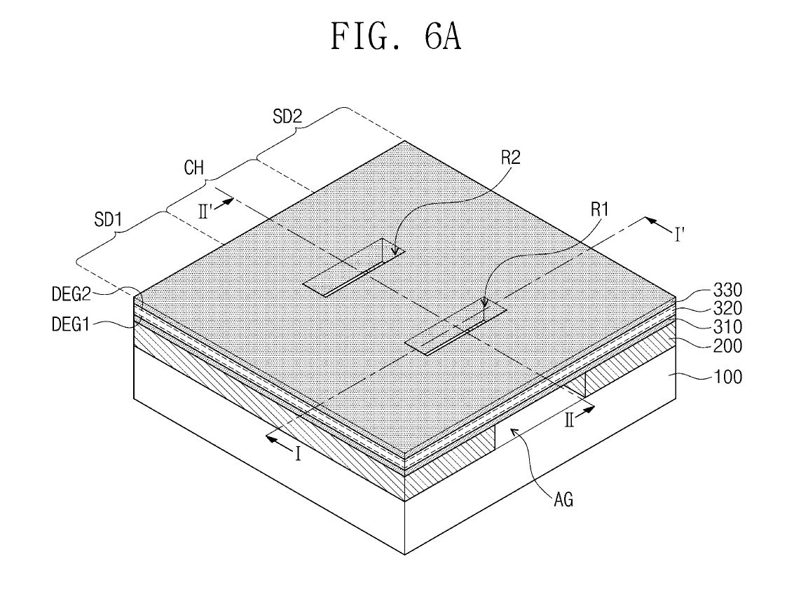

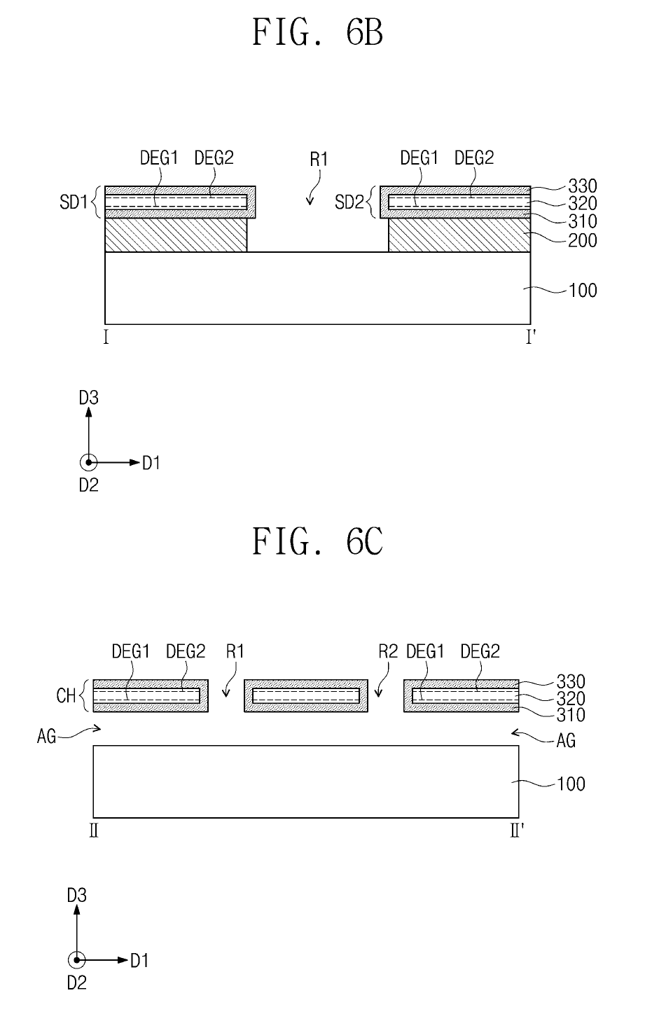

Referring to FIGS. 6A, 6B, and 6C, a third nitride semiconductor film 330 may be formed on the second nitride semiconductor film 320. In the exemplary embodiments, forming the third nitride semiconductor film 330 may include performing a Metal Organic Chemical Vapor Deposition (MOCVD) process. The third nitride semiconductor film 330 may include substantially the same material as the first nitride semiconductor film 310. For example, the third nitride semiconductor film 330 may include AlGaN. Due to the difference in lattice constant between the third nitride semiconductor film 330 and the second nitride semiconductor film 320, the second two-dimensional electron gas layer DEG2 may be formed in the second nitride semiconductor film 320. The second two-dimensional electron gas layer DEG2 may be provided on the second nitride semiconductor film 320 and may be adjacent to the third nitride semiconductor film 330.

The third nitride semiconductor film 330 may cover the upper surface of the second nitride semiconductor film 320 and extend into the first and second recess regions R1 and R2. The third nitride semiconductor film 330 may cover the side surfaces of the first and second nitride semiconductor films 310 and 320 exposed by the first and second recess regions R1 and R2. The first and third nitride semiconductor films 310 and 330 may surround the second nitride semiconductor film 320. The first and third nitride semiconductor films 310 and 330 may be a single film having no boundary. Accordingly, each of the first and second heterojunction source/drain regions SD1 and SD2 and the heterojunction channel regions CH may include the first and third nitride semiconductor films 310 and 330 surrounding the second nitride semiconductor film 320 and the second nitride semiconductor film 320. For example, each of the first and second heterojunction source/drain regions SD1 and SD2 and the heterojunction channel regions CH may include a GaN film and an AlGaN film surrounding the GaN film.

Generally, a gate-all-around device may include one two-dimensional electron gas layer. The second nitride semiconductor film 320 according to the concept of the inventive concept may include two two-dimensional electron gas layers interposed between the first and third nitride semiconductor films 310 and 330. Thus, the electrical characteristics of the gate-all-around device may be improved.

Referring to FIGS. 7A, 7B, 7C, and 7D, gate electrodes GE may be formed on the heterojunction channel regions CH, respectively. Forming the gate electrodes GE may include forming a photoresist pattern (not shown) exposing the heterojunction channel regions CH on the third nitride semiconductor film 330, depositing a conductive material on the exposed heterojunction channel regions CH, and removing the photoresist pattern. In exemplary embodiments, depositing the conductive material may include performing a Plasma Assisted Atomic Layer Deposition (PA-ALD) process.

In other exemplary embodiments, forming the gate electrodes GE may include forming a sacrificial pattern (not shown) exposing the heterojunction channel regions CH on the third nitride semiconductor film 330, depositing a conductive material on the exposed heterojunction channel regions CH, and removing the sacrificial pattern. For example, the sacrificial pattern may comprise SiN. Depositing the conductive material may include performing an Atomic Layer Deposition (ALD) process at a high temperature.

The gate electrodes GE may include a multi-layer structure. For example, each of the gate electrodes GE may include a Ni/Au structure. The gate electrodes GE may surround the heterojunction channel regions CH, respectively. Each of the gate electrodes GE may extend along the surface of the first and third nitride semiconductor films 310 and 330. That is, each of the gate electrodes GE may extend along the upper surface of the third nitride semiconductor film 330, the side surfaces of the third nitride semiconductor film 330 exposed by the first and second recess regions R1 and R2, and the bottom surface of the first nitride semiconductor film 310 exposed by the air gap AG. For example, the gate electrode GE may have an annular shape.

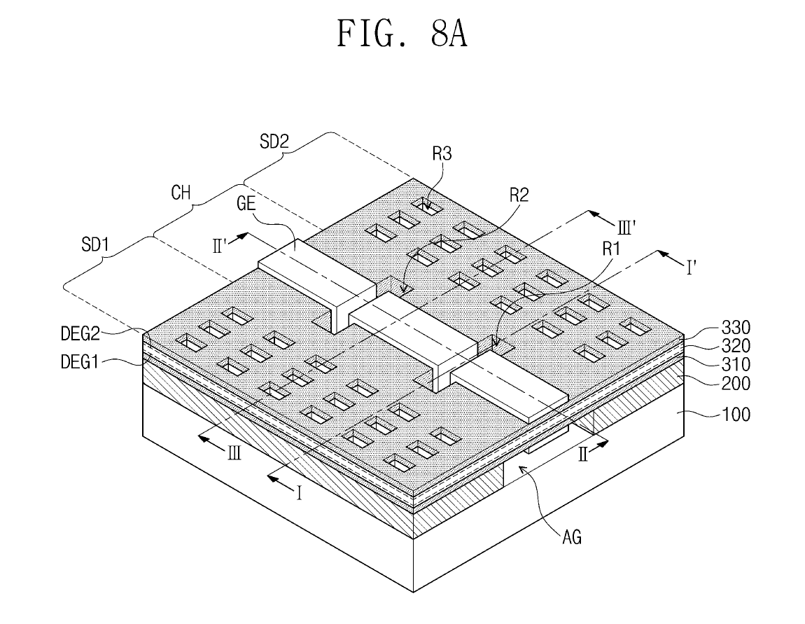

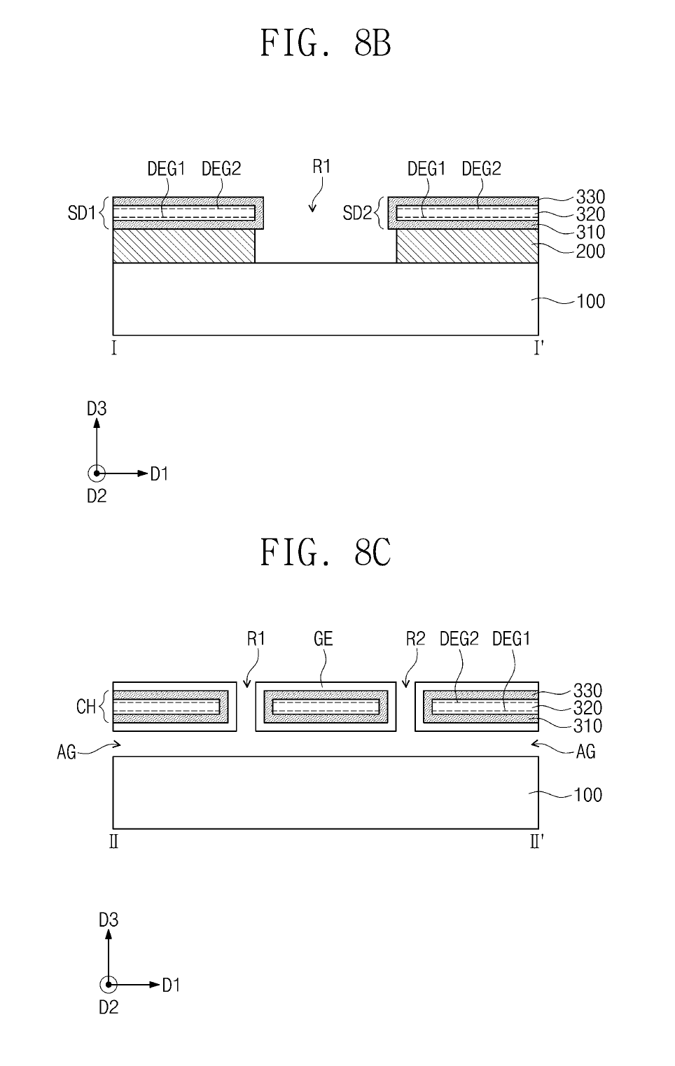

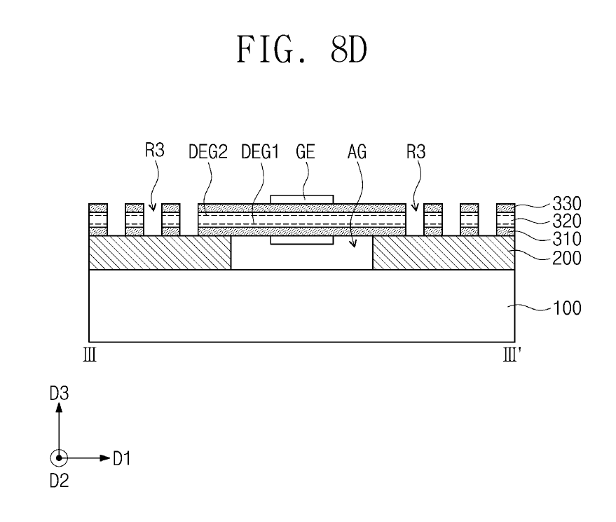

Referring to FIGS. 8A, 8B, 8C, and 8D, third recess regions R3 may be formed in the first and second heterojunction source/drain regions SD1 and SD2. Forming the third recess regions R3 may include forming a photoresist pattern (not shown) exposing regions, where the third recess regions R3 are to be formed, on the third nitride semiconductor film 330, patterning the first to third nitride semiconductor films 310, 320, and 330 by performing an anisotropic etching process using the photoresist pattern as an etching mask, and removing the photoresist pattern. The third recess regions R3 may penetrate the first to third nitride semiconductor films 310, 320, and 330 to expose the upper surface of the insulating layer 200.

In the exemplary embodiments, the side surfaces of the first to third nitride semiconductor films 310, 320, and 330 exposed by each of the third recessed regions R3 are surface-treated so that the surface characteristics of the side surfaces damaged during the anisotropic etching process may be improved. For example, the surface treatment may provide tetramethylammonium hydroxide (TMAH) in the third recessed regions R3 to prevent the side surfaces of the first to third nitride semiconductor films 310, 320, and 330 from being exposed to the TMAH.

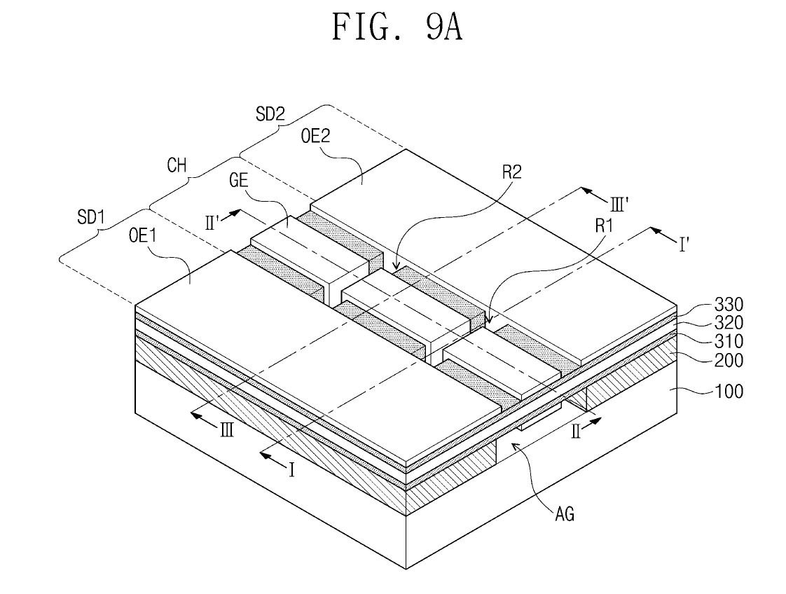

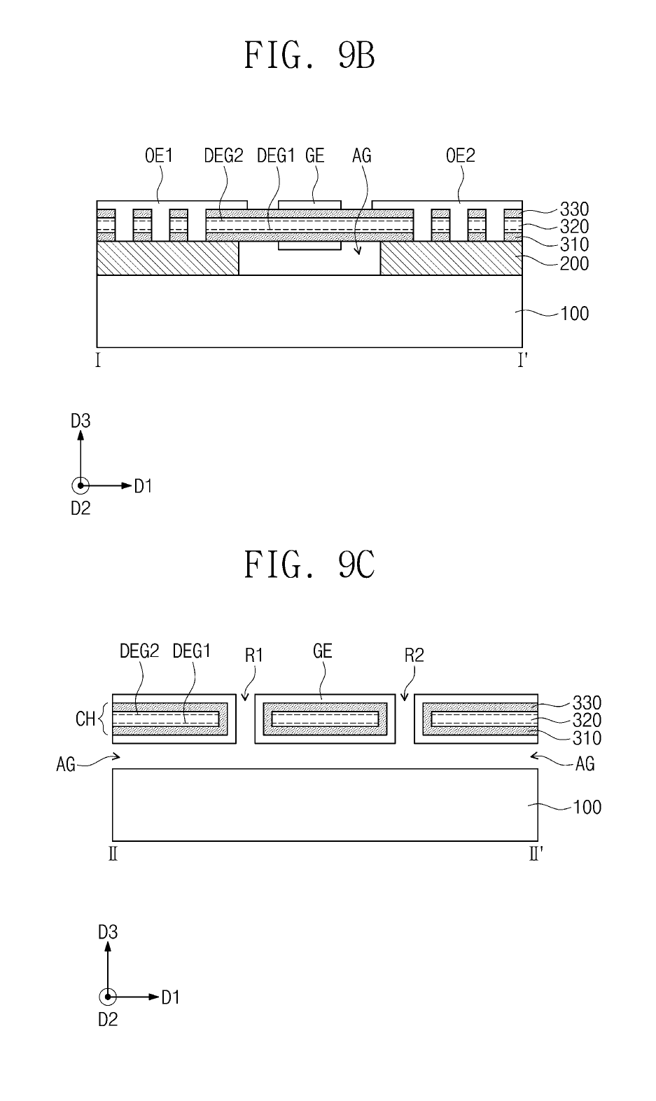

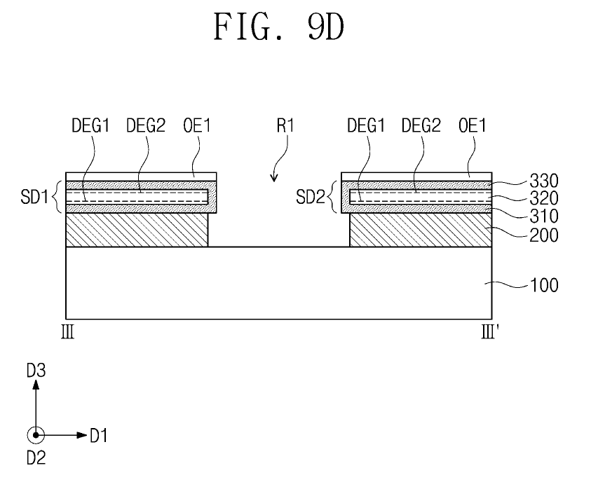

Referring to FIGS. 9A, 9B, 9C, and 9D, a first ohmic electrode OE1 and a second ohmic electrode OE2 may be formed on first and second heterojunction source/drain regions SD1 and SD2, respectively. Forming the first and second ohmic electrodes OE1 and OE2 may include forming a photoresist pattern (not shown) exposing the first and second heterojunction source/drain regions SD1 and SD2 on the third nitride semiconductor film 330, depositing metals on the first and second heterojunction source/drain regions SD1 and SD2, and removing the photoresist pattern. Each of the first and second ohmic electrodes OE1 and OE2 may include a multi-layer structure. For example, each of the first and second ohmic electrodes OE1 and OE2 may include a Ti/Al/Ni/Au structure.

Generally, forming the ohmic electrode may include performing a high-temperature rapid heat treatment process. During the high-temperature rapid heat treatment process, the shape of the ohmic electrode may be deformed. Accordingly, the gate-all-around device may not have the required electrical characteristics. That is, the reliability of the gate-all-around device may be low.

Forming the first and second ohmic electrodes OE1 and OE2 according to the concept of the inventive concept may not include a heat treatment process. Accordingly, the gate-all-around device may have the required electrical characteristics. As a result, the reliability of the gate-all-around device may be improved.

Each of the first and second ohmic electrodes OE1 and OE2 may cover the upper surface of the third nitride semiconductor film 330 and extend into the third recessed regions R3. The first and second ohmic electrodes OE1 and OE2 may fill the third recess regions R3. Each of the first and second ohmic electrodes OE1 and OE2 may directly contact the first and second electron gas layers DEG1 and DEG2. Thus, the electrical characteristics of the gate-all-around device may be improved.

According to the concept of the inventive concept, a gate-all-around device with improved reliability may be provided.

According to the concept of the inventive concept, a gate-all-around device with improved process efficiency may be provided.

Although the exemplary embodiments of the inventive concept have been described, it is understood that the inventive concept should not be limited to these exemplary embodiments but various changes and modifications can be made by one ordinary skilled in the art within the spirit and scope of the inventive concept as hereinafter claimed.

What is claimed is:

1. A gate-all-around device comprising:
a substrate;
a pair of heterojunction source/drain regions provided on the substrate;
a heterojunction channel region provided between the pair of heterojunction source/drain regions; and
a pair of ohmic electrodes provided on the pair of heterojunction source/drain regions, respectively,
wherein each of the pair of heterojunction source/drain regions comprises a pair of two-dimensional electron gas layers, and
the pair of ohmic electrodes extends toward an upper surface of the substrate and passes through the pair of heterojunction source/drain regions, respectively.

2. The gate-all-around device of claim 1, wherein each of the pair of ohmic electrodes is electrically connected to the pair of two-dimensional electron gas layers.

3. The gate-all-around device of claim 1, wherein each of the pair of heterojunction source/drain regions comprises:
a pair of first nitride semiconductor films spaced apart from each other along a direction perpendicular to the upper surface of the substrate; and
a second nitride semiconductor film interposed between the pair of first nitride semiconductor films.

4. The gate-all-around device of claim 1, further comprising:
an insulating layer interposed between each of the pair of heterojunction source/drain regions and the substrate; and
an air gap provided between the heterojunction channel region and the substrate.

5. The gate-all-around device of claim 1, wherein the heterojunction channel region comprises:
a second nitride semiconductor film extending in the first direction; and
a first nitride semiconductor film surrounding the second nitride semiconductor film.

6. The gate-all-around device of claim 5, further comprising a gate electrode surrounding the heterojunction channel region,
wherein the first nitride semiconductor film is interposed between the second nitride semiconductor film and the gate electrode.

7. The gate-all-around device of claim 6, wherein each of the gate electrode and the heterojunction channel region is provided in plural, and
wherein the plurality of gate electrodes surround the plurality of heterojunction channel regions.

8. A method of fabricating a gate-all-around device, the method comprising:
forming a first nitride semiconductor film and a second nitride semiconductor film sequentially stacked on a substrate;
sequentially patterning the second nitride semiconductor film and the first nitride semiconductor film to form a first recess region and a second recess region;
forming a third nitride semiconductor film on an upper surface of the second nitride semiconductor film and side surfaces of the first and second nitride semiconductor films exposed by each of the first and second recess regions;
forming a gate electrode on the first and third nitride semiconductor films disposed between the first and second recess regions; and
forming first and second ohmic electrodes on the third nitride semiconductor film, the first and second ohmic electrodes being spaced apart from each other in a first direction parallel to an upper surface of the substrate with the gate electrode therebetween.

9. The method of claim 8, further comprising:
forming an insulating layer interposed between the first nitride semiconductor film and the substrate; and
providing an etchant into the first and second recess regions to remove the insulating layer disposed between the first and second recess regions,
wherein the insulating layer is removed to form an air gap between the first nitride semiconductor film and the substrate.

10. The method of claim 9, wherein the gate electrode covers an upper surface of the third nitride semiconductor film and extends along surfaces of the third nitride semiconductor film exposed by the first recess region, the air gap, and the second recess region.

11. The method of claim 8, wherein the forming of the first and second ohmic electrodes comprises:
forming third recessed regions penetrating the first to third nitride semiconductor films on both sides of the gate electrode; and
depositing metals on the third nitride semiconductor film to fill the third recess regions.
